(19) United States
(12) Patent Application Publication
(10) Pub. No.: US 2009/0189151 A1
(43) Pub. Date: Jul. 30, 2009

(54) METHOD FOR SEPARATING A NON-EMISSION REGION FROM A LIGHT EMISSION REGION WITHIN AN ORGANIC LIGHT EMITTING DIODE (OLED)

(75) Inventors: Herbert Friedrich Börner, Aachen (DE); Hans-Peter Loebl, Monschau-Imgenbroich (DE)

Correspondence Address: Philips Intellectual Property and Standards, P.O. Box 3001, Briarcliff Manor, NY, 10510-8001, US

(73) Assignee: Koninklijke Philips Electronics N.V., Eindhoven (NL)

(21) Appl. No.: 12/301,033

(22) PCT Filed: May 11, 2007
(86) PCT No.: PCT/IB2007/051784

§ 371 Date: Nov. 17, 2008

(30) Foreign Application Priority Data
May 22, 2006 (EP) 06114317.8

(51) Int. Cl. H01L 51/52; H01L 27/32; H01L 51/56; H01L 21/04

(52) U.S. Cl. 257/40; 257/79; 438/99; 438/42; 257/E51.001; 257/E33.001

(57) ABSTRACT

The present invention relates to a method for separating at least one non-emission region (16) from at least one emission region (15) within an organic light emitting diode (OLED) (1), which comprises a substrate material (10) as a carrier, whereas the substrate material (10) is coated and/or superimposed by at least one anode layer (11) and at least one cathode layer (13), whereas at least one functional layer (12) is sandwiched in between the layers (11, 13) for emitting light, whereas impressing a voltage in between the anode layer (11) and the cathode layer (13) causes an emission of light within the emission region (15), and whereas the separating of the one non-emission region (16) is caused by scribing a groove (14) into at least the anode and/or the cathode layer (11, 13), in order to insulate the electrical current within at least one layer (11, 13) from the emission region (15) into the non-emission region (16), whereas the groove (14) is performed by mechanical scribing, applying a scribing tool (17).

This invention relates to a method for separating at least one non-emission region from at least one emission region within an organic light emitting diode (OLED), which comprises a substrate material as a carrier, whereas the substrate material is coated and/or superimposed by at least one anode layer and at least one cathode layer, whereas at least one functional layer is sandwiched in between the layers for emitting light, whereas impressing a voltage in between the anode layer and the cathode layer causes an emission of light within the emission region.

Illumination devices basing on organic light emitting diodes (OLEDs) are of great interest as superior flat-panel systems. These systems utilize current passing through a thin-film of organic material to generate light. The colour of light emitted and the efficiency of the energy conversion from current to light are determined by the composition of the organic thin-film material. However, the OLEDs comprise a substrate material as a carrier layer, which may be made of glass or an organic material or from non transmittive materials such as metal foils. Furthermore organic light emitting diodes consist of at least one very thin layer with a layer thickness of approx. 100 nm of organic substances on a glass substrate covered with an electrically conducting and optically transparent oxide. This organic layer usually is performed as an Indium-Tin-Oxide (ITO).

Usually the ITO-layer forms the anode and a layer of Aluminium forms the cathode, whereas the Aluminium layer features a thickness of approx. 100 nm and thus a thickness like the ITO-layer. Aluminium of such a thickness works as a mirror, such that the emission is through the transparent ITO anode and the transparent substrate only. If the cathode metal is thin enough to be partially transparent, part of the light can also be emitted through the cathode. When a voltage between 2V and approx. 10V is applied between anode and cathode, charges are injected into the organic layers and the organic stack emits light.

Between the anode layer, which is e.g. the Indium-Tin-Oxide (ITO) layer and the cathode layer like the Aluminium layer are arranged several functional layers, which may be a hole injection layer, a hole transport layer, a emission layers, which may be performed as fluorescent and/or phosphorescent emitter layers, a hole blocking layer, an electron transport layer and/or additionally an electron injection layer, whereas these layers feature a thickness of approximately 5 nm to 100 nm. The OLED may also consist of a stack of OLEDs as described above, which are separated by conductive layers such as ITO or thin metal films or by so-called charge generation layers, which consist of p-doped n-doped layers with and without barrier layers in between. Depending on the layer stack the top emission, which emits by passing the Aluminium cathode or a bottom emission by passing the light through the ITO-layer may represent different types of organic light emitting diodes.

The power supply of the anode layer and/or cathode layer may be performed by an electrical contacting, which supplies the current through at least one edge of the OLED panel. If regions within the OLED panel have to be decoupled from the current supply, in order to render these regions as dark regions, the panel has to be separated into an emission region and a non-emission region. The emission region is supplied by electrical current, whereas the non-emission region is separated from the current supply by performing electrical breaks or discontinuations within the entire OLED-panel. The separation of the non-emission regions from the emission regions is usually performed by laser radiation, whereas the laser radiation causes grooves inside the coated layers, which means, that the electrical current is interrupted by the grooves. Usually these grooves feature closed inside contours, to perform a reliable interruption of the electrical current.

This technique may be necessary to cut out hotspots inside the entire OLED-panel, which can be an electrical short for example, and which make the OLED inoperable. If these electrical shorts are not separated from the emission region, the entire OLED-panel may be destroyed. Thus, it is necessary to cut out theses hotspots saving the rest of the OLED-panel. In particular, since the organic layers and the superimposed Aluminium cathode are only 200 nm thick, they can easily be damaged. Especially at the edges of the panel, electrical shorts may appear, which have to be cut out electrically of the rest of the emitting region. Another application of generating non-emission region can be seen in creating of graphics, paintings or scriptures inside the OLED-panel, whereas basing on the appearance of dark regions within the non-emission regions a graphic or a scripture can be applied for an alternative kind of neon writing for markers, signals, private use or any other kind if signalising.

As well as production failures during operation, OLEDs sometimes develop short circuits, which tend to destroy the device completely, since they usually grow up to the edge of the device. A method for curing the problem is to cut out the shorted region by a laser beam through the glass substrate. The laser cut isolates the problem area electrically from the cathode and perhaps also the anode, without creating new shorts. This method works reliable, but needs rather expensive equipment. The laser cutting can also be employed to create design in the OLED by blackening certain regions of the device, but is next to the high costs sumptuous in handling and operating.

A scribing method basing on laser radiation is known in the document WO86/03460. In this document is disclosed a flexible electroluminescent panel with a transparent electrode, applied to a flexible sheet of transparent dielectric material to form a base. A coating is supplied over the electrode in the form of a polymer laminating resin which has been activated by an activator containing diisocyanate or isocyanate and which contains an electroluminescent phosphor dispersed therein, to form a panel section. When suitable electrodes are attached, two such panel sections may be laminated together, in face-to-face relationship, phosphor to phosphor, to form a completed panel which may then be cut, punched, spindled or trimmed as desired or necessary without degeneration and without shorting, providing light to the edges. The resistance to shorting is due primarily to the fact, that the Indium-Tin-Oxide electrode layers are exceedingly thin, in order of a few Angstroms, and therefore are essentially incapable of forming a short circuit when punched or cut.

Yet another field of applying separation methods within an electroluminescent lamp is disclosed in the document WO93/00695. In this document an electroluminescent sheet-form lamp is disclosed, which comprises a transparent insulation layer, a transparent first conductive layer below said insulation layer forming a first electrode, a layer of phosphor material below said first conductive layer, a layer of dielectric material below said phosphor layer, a second conductive layer below said dielectric layer forming a second electrode, which features an edge region within said lamp susceptible edge region of a detrimental, electrically conductive path, whereby an improvement is disclosed, which relates to a main portion of said one conductive layer which is insulated from the susceptible edge region by isolation provided along at least a portion of the perimeter of the lamp as a result of removal of said pre-applied conductive coating such that, at the region of connection is electrically isolated from said susceptible region, and cutting said lamp from said panel of larger dimension to provide a lamp for which the formation of said conductive path in said edge region does not cause an adverse effect.

Relating to the present application field of OLEDs, the scribing of the layers like the anode layer or cathode layer is performed by laser radiation, whereas the laser beam ablates the at least one coated layer material, to perform an electrically separation of different emission regions. Unfortunately, the application of laser systems is quite expensive and laborious. Usually the operation with lasers requires qualified personal and accordant safety measures. A laser ablation system is inflexible and not suitable for an instant use within a short time.

Thus, the invention has for its object to eliminate the above mentioned disadvantages. In particular, it is an object of the invention to provide a method for separating non-emission regions from emission regions within one organic light emitting diode in an ordinary way.

This object is achieved by a method for separating a non-emission region from a light emission region within an organic light emitting diode (OLED) as taught by claim 1 of the present invention. Advantage embodiments of the inventive method are defined in the subclaims.

The invention discloses, that the separating of at least one non-emission region is caused by scribing a groove into at least the anode and/or the cathode layer in order to insulate the electrical current within at least one layer from the emission region into the non-emission region, whereas the groove is performed by mechanical scribing, applying a scribing tool.

According to the invented method, the use of a laser source can be omitted. The mechanical scribing is performed by the use of a scribing tool, whereas the scribing tool comprises a mechanical means, which may be performed as a fine cutting point, to scribe a groove into the at least one layer. Due to the required separation of at least one layer the scribing of a groove into the layers is not limited to both layers, whether the anode layer or the cathode layer may be separated by scribing the groove. If only the Aluminium layer is electrically insulated, the non-emission region can not be supplied due to the failed contacting. On the other hand it is sufficient to perform the separating within the ITO-layer, whereas it is not said, that if the ITO-layer is arranged adjacent to the substrate material, or if the cathode layer like the Aluminium layer is directly coated on the substrate material. In each case the scribing of at least one of the named layers is sufficient to generate dark regions by interrupting the electrical current due to the scribed groove.

According to another embodiment of the invention the mechanical means may be performed as a needle, a knife, a razor blade or a graver, which is used as the scribing tool. Thus, the scope of invention is not limited to any specific design of the mechanical means, as long as the mechanical means features at least one fine cutting point like a spike or a tip, which is pointy and is suitable to scrape the at least one layer. Thus, the mechanical means is applied on the coating side of the OLED, so that the substrate material is not damaged or not affected by the application of scribing with the scribing tool.

Fortunately the groove is performed as a closed inside contour, producing an electrical separation of the inner region from the outer region of the closed inside contour. If the groove would not be performed as a closed inside contour, a kind of electrical bridge can remain within the OLED-panel, which means that the electrical separation of the both emission regions is not performed reliable. Granted that the region, which has to be separated to generate a non-emission region, is positioned at the edge of the OLED-panel, and which is partly bordered by the edge of the panel, it is evident, that the groove has not to be performed as a closed contour.

According to another embodiment of the invention the anode layer is performed as an Indium-Tin-Oxide layer, whereas the Indium-Tin-Oxide layer is scribed by the scribing tool to generate the groove in this layer, in order to insulate the electrical current between both sides of the groove bands. According to the cathode layer it is suggested to perform the cathode layer as an Aluminium layer, whereas the Aluminium layer is scribed by the scribing tool to generate a groove in this layer, in order to isolate the electrical current between both sides of the groove bands. Different layer materials, which are performed as the cathode layer, may be a calcium-layer, a magnesium/silver-layer or any other cathode material.

Relating to the movement of the scribing tool across the OLED-panel, the scribing tool on the OLED may be processed by hand or by a handling system. In the case, that an instant repair of hotspots has to be performed or a scribing, e.g. a scribing of letters, which shall be performed by hand, the scribing tool can be performed with a handle being handheld in an advantage way. In the case, that the scribing on the OLED-panel must be performed by a computer controlled handling system, the scribing tool can be mounted to an handling system, which can be a X-Y-handling, which may write letters or graphics of any different kinds inside the OLED-panel, to perform the scribing system as a “computer to plate” system.

The present invention also relates to an organic light emitting diode (OLED) comprising a substrate material as a carrier, whereas the substrate material is coated and/or superimposed by at least by one anode layer and at least one cathode layer, whereas at least one functional layer is sandwiched in between the layers for emitting light, whereas impressing a voltage in between the anode layer and the cathode layer causes an emission of light within at least one emission region, and whereas the OLED features at least one non-emission region, which is caused by scribing a groove into at least the anode and/or cathode layer in order to insulate the electrical current within at least one layer from the emission region into the non-emission region, whereas the layers, comprising at least one groove feature a homogenous appearance in the entire surface without any thermal influence, whereas in particular the bands of the groove are unaffected of thermal influence. Thus, the means for scribing the groove into at least one layer is performed without laser or any different radiation. Unfortunately, the use of laser radiation for an ablation process, generating the groove to the layer material, leads to a thermal influence, which signifies a downgrade of the scribing quality. According to the present invention the OLED, which features scribed grooves, is unaffected of thermal influence within the entire surface of the OLED. In particular the groove bands are not affected, because the scribing tool bases on a “cold ablation”.

According to the organic light emitting diode of the present invention, the groove features a closed inside contour obtaining a plain current separation of a non-emission region within the closed inside contour. Within this closed inside contour may be located a hotspot, which is in particular an electrical short. By the electrical separating of the electrical short, the OLED may be cured by an easy salvaging process.

Furthermore, the present invention relates to an organic light emitting Diode (OLED) with a method for separating a non-emission region from a light emission region.

The aforementioned method for separating different regions within an OLED-panel and the OLED itself, as well as claimed components and the components to be used in accordance with the invention in the described embodiments, are not subject to any special exceptions with respect to size, shape, material selection as technical concept such that the selection criteria are known in the pertinent field can be applied without limitations. Additional details, characteristics and advantages of the object of the present invention are disclosed in the subclaims and the following description of the respective figures—which are an exemplary fashion only—shows a preferred embodiment of the illumination device according to the present invention. Theses figures are:

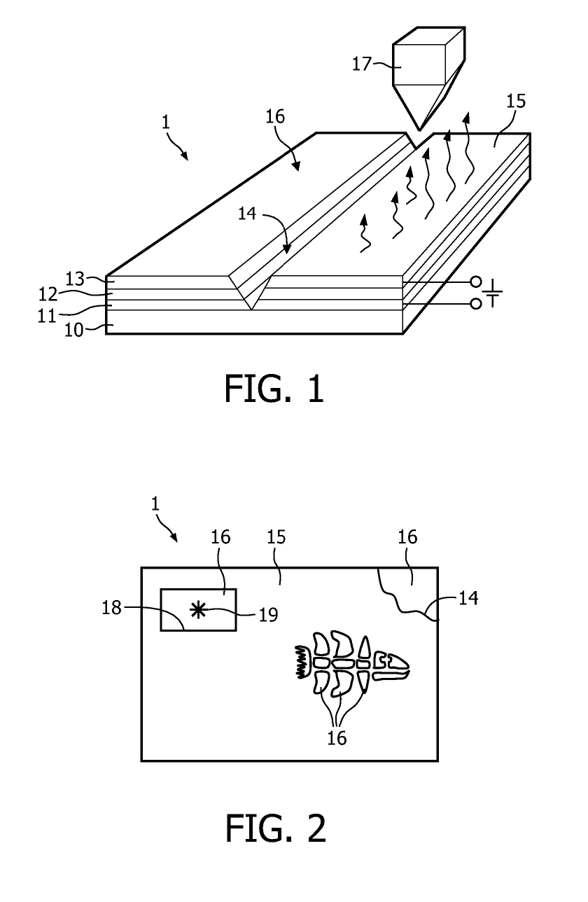

FIG. 1 a schematically perspective view of an organic light emitting diode (OLED), whereas the applied layers are not in true scale; and

FIG. 2 shows a plan view of an OLED-panel with a closed inside contour, comprising a hotspot, a non-emission region, which is bordered by the edge of the panel and an exemplary fashion of a graphic application within the OLED-panel.

FIG. 1 shows a perspective view of an organic light emitting diode (OLED) 1, whereas this schematic drawing is not in a true scale regarding to the dimensions of the different features and in particular the relation between the thicknesses of different layers does not relate to a true scale. Thus, the drawing in FIG. 1 is only taught as a schematic view.

The OLED 1 comprises a substrate material 10, which can be formed by a glass panel or a panel made of organic material or metal. Thus, the substrate material 10 forms the basic structure, on which different layers are superimposed. These layers are at least an anode layer 11, which can be performed as an Indium-Tin-Oxide layer (ITO-layer), and which is superimposed by a plurality of different functional layers 12, whereby the functional layers 12 are only shown as a single functional layer 12 to simplify matters. These functional layers 12 may comprise at least a hole injection layer, a hole transport layer, emission layers (fluorescent and/or phosphorescent emitter), in which the emission of light is realised, and at least one hole blocking layer, an electron transport layer and at least one electron injection layer, whereas the different layers are usually very thin, limited to a thickness of approximately 10 nm each. The top layer is a cathode layer 13, which sandwiches the different functional layers 12 between the anode layers 11. A contacting of power supply is schematically shown between the anode layer 11 and the cathode layer 13.

When a current is supplied to the anode layer 11 and the cathode layer 13, a light emitting occurs across the entire surface of the OLED 1, which is schematically shown by arrows across the surface. The emitting surface, which is contacted by the power supply, is indicated by the emission region 15. Between the emission region 15 and the non-emission region 16 is located a groove 14, which separates the both regions 15, 16 by interrupting the current in at least one of the layers 11 or 13. The groove 14 is shown schematically, and may separate all layers, which are superimposed on the substrate material 10. For an isolating of the current flow from the emission region 15 to the non-emission region 16 it may be sufficient to separate only the cathode layer 13, whereas the thicknesses of the different layers are in a range between the lower nanometre field, and thus it is not significant, which of the layers 11 to 13 is scribed in particular. The scribing of the groove 14 is performed by a scribing tool 17, which features a fine cutting point. The scribing tool 17 may be performed as a needle, a knife, a razor blade or for instance a graver tool, which is suitable to scribe the groove 14 into the plurality of layers, whereas the wide of the groove 14 is not limited to a V-performance. It is obvious, that the relation between the dimensions of the scribing tool 17 and the thickness of the different layers 11 to 13 leads to a groove 14, which features a very large wide in relation to the height. The scribing the groove with the scribing tools 17 is suitable to separate the layers 11 to 13 without damaging the substrate material 10, which mainly depends on the hardness of the substrate layers 10.

FIG. 2 shows a plan view of an organic light emitting diode 1, on which different features are shown, and which are obtained by separating a non-emission region 16 from an emission region 15. If the non-emission region 16 is bordered by the edge of the OLED 1, the groove 14 has not to be performed as a closed inside contour 18. If the non-emission region 16 is located within the emission region 15, the groove 14 has to be performed as a closed inside contour 18, in order to ensure a reliable separation of the electrical current between the emission region 15 and the non-emission region 16. As an example a graphic is shown, which features a fish-silhouette, and which is shown in outlines. These outlines are performed as closed inside contours, to ensure the reliable separation of the electrical current. If the OLED 1 is power supplied, the emission region 15 begins to illuminate, whereby the closed inside contour of the fish-silhouette remain dark. This principle leads to the suitability of OLEDs 1 to form active illuminating devices. The graphic can also relate to scriptures or similar applications.

If the OLED 1 features a hotspot 19, which may be an electrical short, usually the entire OLED can be damaged. Thus, it is evident to enclose the hotspot 19 by a closed inside contour 18, in order to withdraw the electrical current from the hotspot 19. This repair-principle is suitable for salvaging the OLED 1, which can be of further usage. Furthermore, cut-off regions of the cathode can be lifted of with e.g. adhesive tape to create windows in the OLED for a decorative proposes. By inspecting the OLED 1 with a microscope through the glass substrate the application of the mechanical scribing method can easily be checked.

The present invention is not limited by the embodiment described above, which is represented as an example only and can be modified in various ways within the scope of protection defined by the appended patent claims. Thus, the invention is also applicable to different embodiment, in particular of the design of the OLED 1 and/or the structure of scribing. It is understood, that the scope of protection is also directed to stacked OLEDs, which are separated by conductive layers such as ITO or thin metal films or by so-called charge generation layers, which consist of p- doped n-doped layers with and without barrier layers in between.

### LIST OF NUMERALS

1 organic light emitting diode (OLED)

10 substrate material

11 anode layer

12 functional layer

13 cathode layer

14 groove

15 emission region

16 non-emission region

17 scribing tool

18 closed inside contour

19 hotspot

1. A method for separating at least one non-emission region from at least one emission region within an organic light emitting diode (OLED), the OLED comprising a substrate material having at least one anode layer and at least one cathode layer (13) disposed thereon, and at least one functional layer sandwiched in between the anode and the cathode layers for emitting light, wherein impressing a voltage in between the anode layer and the cathode layer causes an emission of light within the emission region, the method comprising scribing a groove into at least one of the anode and the cathode layer, by a mechanical scribing tool in order to insulate the electrical current therein from the emission region into the non-emission region to obtain at least one dark region within the OLED.

2. The method as claimed in claim 1, wherein the scribing tool comprises a fine cutting point.

3. The method as claimed in claim 1, wherein the scribing tool comprises a needle, a knife, a razor blade, or a graver.

4. The method as claimed in claim 1, wherein the groove is configured as a closed inside contour, producing an electrical separation of the inner region from the outer region of the closed inside contour.

5. The method as claimed in claim 1, wherein the anode layer comprises indium-tin oxide and wherein the anode layer is mechanically scribed to generate the groove therein.

6. The method as claimed in claim 1, wherein the cathode layer comprises aluminum and wherein the cathode layer is mechanically scribed to generate the groove therein.

7. The method as claimed in claim 1, wherein the movement of the scribing tool on the OLED is processed by hand without laser radiation.

8. (canceled)

9. Organic light emitting diode (OLED) comprising a substrate material having at least one anode layer and at least one cathode layer disposed thereon, and at least one functional layer sandwiched in between the anode and cathode layers for emitting light, wherein impressing a voltage in between the anode layer and the cathode layer causes an emission of light within at least one emission region, the OLED comprising at least one non-emission region, defined by a groove mechanically scribed into at least one of the anode and the cathode layers, in order to insulate the electrical current therein from the emission region into the non-emission region and wherein the bands of the groove are unaffected by thermal influence.

10-11. (canceled)

12. Organic light emitting diode (OLED) as claimed in claim 9, wherein the groove defines a closed inside contour for obtaining a plain current separation of a non-emission region within the closed inside contour.

13. Organic light emitting diode (OLED) as claimed in claim 12, wherein an electrical short is located within the closed inside contour.

14. (canceled)
